(19) United States
(12) Patent Application Publication
(10) Pub. No.: US 2006/0172204 A1
(43) Pub. Date: Aug. 3, 2006

(54) Systems, masks and methods for printing contact holes and other patterns

(76) Inventors: Danping Peng, Fremont, CA (US); Yong Liu, Fremont, CA (US); Daniel S. Abrams, Mountain View, CA (US)

Correspondence Address: WILSON SONSINI GOODRICH & ROSATI, 650 PAGE MILL ROAD, PALO ALTO, CA, 94304-1050, US

(21) Appl. No.: 11/335,018

(22) Filed: Jan. 18, 2006

Related U.S. Application Data
(60) Provisional application No. 60/723,653, filed on Oct. 4, 2005.
(60) Provisional application No. 60/645,276, filed on Jan. 18, 2005.

(51) Int. Cl. G03C 5/00; G03F 1/00

(52) U.S. Cl. 430/5; 430/394; 430/311

(57) ABSTRACT

Contact hole patterns are disclosed having a plurality of peripheral regions formed around a target area in which a contact hole is to be formed. The peripheral regions visually resemble “lobes” or “leaves” extending outwards towards the periphery of the target area. The lobes may be disjoint or connected to each other. Present methods can be used to prepare masks for printing contact holes on wafers, as well as to prepare design patterns for laser-writers or direct-write lithography in order to print contact holes on masks or directly on wafers. The methods apply to both binary and phase-shift mask designs with varying illuminations.

### CROSS REFERENCE

This application claims the benefit of U.S. Provisional Application No. 60/723,653, filed Oct. 4, 2005 and U.S. Provisional Application No. 60/645,276, filed Jan. 18, 2005, which are incorporated herein by reference in their entirety.

### FIELD OF INVENTION

The invention pertains in general to semiconductor manufacturing, and in particular to patterns for printing contact holes and other patterns on substrates.

### BACKGROUND

Lithography processing represents an essential technology for manufacturing integrated circuits (IC) and micro electromechanical devices (MEMS). Lithographic techniques are used to define and write patterns, geometries, features and shapes onto an integrated circuit die or semiconductor wafer. The patterns are generally defined by a set of polygons, contours, lines, boundaries, edges or curves representing or enclosing the boundaries of the regions which constitute the patterns.

Demand for increased density of features on dies and wafers has resulted in the design of circuits with decreasing feature dimensions. However, due to the wave nature of light, as dimensions approach sizes comparable to the wavelength of the exposure light used in the lithography process, the resulting wafer patterns tend to deviate from the corresponding photomask (hereinafter also referred to as “mask”) patterns and degrade due to unwanted distortions and artifacts.

Techniques such as optical proximity correction (OPC) address this problem by pre-distorting the mask pattern, for example using serifs or assist features. However, such approaches do not consider the full spectrum of possible mask patterns as they set out to generate a suitably pre-distorted pattern, and as a result generate sub-optimal mask patterns which may not print robustly or may not print correctly at all.

Contact holes are one of the most difficult features to manufacture in any generation, due to 2-dimensional exposure light diffraction effects. Serifs and assist features have been proposed for improving the process window. However, serifs in general do not improve depth of focus, and while assist features can improve depth of focus, they remain inadequate in many cases. Alternating phase-shift masks have been shown to improve depth of focus, but their cost is higher than typical binary and attenuated phase-shift masks. Therefore, an approach employing binary or attenuated phase-shift masks and achieving larger depth of focus is desirable. Similarly, more accurate printing approaches achieving larger depth of focus for use with laser-writers or direct-write lithography are desirable as well.

### SUMMARY OF THE INVENTION

Aspects of the invention provide systems, masks and methods for printing contact holes on substrates. Contact hole patterns are disclosed having a plurality of peripheral regions formed around a target area in which a contact hole is to be formed. The peripheral regions may form “lobes” extending outwards towards or beyond the periphery of the target area. The lobes may be disjoint or connected to each other. The described patterns and methods can be used to prepare masks for printing contact holes on wafers, as well as to prepare design patterns for laser-writers or direct-write lithography in order to print contact holes or other patterns on masks or directly on wafers. The methods apply to both binary and phase-shift mask designs with varying illuminations. Similar patterns and methods may also be used for printing deep trenches in some embodiments.

In one example, a mask is provided for forming a contact hole on a substrate in approximation with a target pattern. The mask includes a mask pattern for the contact hole with a plurality of lobes disposed around the region of the mask corresponding to the target pattern for the contact hole. At least a portion of each lobe extends outside of the region corresponding to the target pattern. In this example, the portions of the lobes that extend outside the region corresponding to the target pattern include at least twenty percent (20%) of the area of the mask pattern. In other examples, the lobes may extend outside the region corresponding to the target pattern by 10%-100% or any range subsumed therein.

In another example, a mask is provided for forming a contact hole on a substrate in approximation with a target pattern. The mask includes a mask pattern for the contact hole. The mask pattern has a plurality of lobes disposed around the region of the mask corresponding to the target pattern for the contact hole, with the majority of each lobe extending outside of the region corresponding to the target pattern. In some examples, each lobe has a narrow region within the region corresponding to the target pattern and a wider region outside the region corresponding to the target pattern. In another example, a mask is provided with a mask pattern having a plurality of lobes disposed around the region of the mask corresponding to the target pattern for the contact hole. Each lobe has a width that varies along the length of the respective lobe, and the widest portion of each lobe is outside the region of the mask corresponding to the target pattern.

In other aspects, a mask pattern may be provided with at least four lobes. The mask pattern may also have a central region within the region corresponding to the target pattern. In example embodiments, the central region may have an area less than fifty percent (50%) of the region corresponding to the target pattern. In other examples, the area of the central region may be less than 80% to 1% of the region corresponding to the target pattern or any range subsumed therein. Some embodiments may have no central region and the lobes may be disjoint from one another.

In other aspects, the lobes may be connected to the central region by a neck, wherein the neck is thinner than each of the lobes and the central region. In other examples, the lobes may be disjoint from the central region.

In other aspects, the target pattern may be a rectangle, square or circle.

In other aspects, the lobes may be disposed symmetrically around the region corresponding to the target pattern. In some examples, each lobe may be offset from an adjacent lobe by about ninety degrees. In some examples, each lobe may be offset by about forty five degrees from a side of the region corresponding to the target pattern.

In other aspects, at least ten percent (10%) to eighty percent (80%) of each lobe (or any range subsumed therein) may extend outside of the region corresponding to the target pattern.

In other aspects, the mask pattern is designed for 380 nm pitch lithography or less, 280 nm pitch or less, and/or 193 nm wavelength light or less.

In other aspects, each lobe may have a length greater than its width. In other examples, the lobes may be approximately triangular. In some examples, the sides of each lobes may extend inward from the vertices of the approximately triangular shape of the lobe. Each lobe may have a narrow portion within the region corresponding to the target pattern and a wider portion outside the region corresponding to the target pattern. In other examples, each of the lobes may extend outside the region corresponding to the target pattern by a distance equal to at least fifty percent (50%) of the length of a side or diameter of the target pattern.

In another aspect, a mask may be provided to form a plurality of contact holes on a substrate in approximation with a target pattern for each of the contact holes. Any of the mask patterns described above may be used in a repetitive fashion to form the plurality of contact holes. In some examples, the mask patterns may be distorted to account for interference from adjacent mask patterns. In some examples an array of 1,000 or 10,000 or one million or more contact holes may be formed.

In another aspect, a mask may be provided to form a contact hole on a substrate in approximation with a target pattern. The mask includes a mask pattern for the contact hole with an outer ring disposed around the region of the mask corresponding to the target pattern for the contact hole. In an example embodiment, most of the outer ring may be outside of the region corresponding to the target pattern. In further aspects, the mask pattern may have an inner ring or circular region that is inside the outer ring.

In another aspect, a mask is provided using any of the above mask patterns configured to form a contact hole having a length within one percent (1%) to twenty percent (20%) of the length of the target pattern both at focus and at 100 nm defocus

In another aspect, a method is provided for forming a contact hole on a substrate. A mask with any of the above mask patterns may be provided and a contact hole may be formed on the substrate using the mask. In one example, the contact hole may be formed by exposing the substrate using the mask in a lithography process. Example lithography processes include processes using any of the following illumination: off-axis illumination, dipole illumination, quadropole illumination, quasar illumination, incoherent illumination, coherent illumination, and an arbitrary illumination configuration. In example embodiments, the lithography may comprises i-line, g-line, 193 nm, 248 nm or immersion optical lithography wavelength in air, water, gas or other fluid. In another aspect, the contact hole is formed using a laser-writer or direct-write tool.

In another aspect, a computer readable medium is provided with data representative of a mask design to be used to form a contact hole on a substrate in approximation with target pattern. The mask design may correspond to any of the masks described above.

In another aspect, a semiconductor device is provided with a contract hole formed by any of the methods described above.

In another aspect, a system is provided for producing a contact hole on a substrate, including a tool configured to accept a computer-readable medium having data representative of any of the above mask pattern and form a contact hole on the substrate based on the mask pattern. The tool may be a laser-writer or a direct-write tool.

It is understood that each of the above aspects of the invention may be used alone or in combination with one or more other aspects of the invention. The above aspects are examples only and are not intended to limit the description or claims set forth below.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1a shows an example contact hole mask pattern 101, in accordance with an embodiment of the present invention.

FIG. 1b illustrates some corresponding contour images, with pattern 102 representing the contact hole target pattern of FIG. 1a, pattern 103 representing the contour image at focus plane, and pattern 104 representing the contour image at 100 nm defocus.

FIG. 1c illustrates an array of contact hole target patterns including target pattern 102.

FIG. 2a shows another example contact hole mask pattern 111 which was prepared for a 380 nm pitch lithography setup to produce the contact hole target pattern 112 on a wafer.

FIG. 2b illustrates some corresponding contour images, with pattern 112 representing the contact hole target pattern of FIG. 2a, pattern 113 representing the contour image at focus plane, and pattern 114 representing the contour image at 100 nm defocus.

FIG. 3 shows a comparison of the depth of focus of a contact hole mask pattern prepared according an embodiment of the present invention versus the depth of focus of a mask pattern with simple bias.

FIG. 4 illustrates a contact hole mask pattern 121 comprising three disjoint regions, prepared to produce the contact hole target pattern 122 on a wafer.

FIG. 5a shows a pattern 131 generated for use as a laser-writing pattern in order to print a rectangular pattern on a mask, in accordance with an embodiment of the present invention.

FIG. 5b shows a pattern 133 that would be produced on a mask using the pattern 131 in a 300 nm laser-writing setup.

FIG. 6 shows yet another example of a pattern 141 generated for use as a laser-writing pattern in order to produce the rectangular pattern 142 on a mask, in accordance with an embodiment of the present invention.

FIGS. 7a,b,c,d illustrate contact hole mask patterns comprising one or more concentric circles, in accordance with an embodiment of the present invention.

FIG. 8 shows a flow diagram illustrating a method for printing contact holes, in accordance with an embodiment of the present invention.

FIG. 9 illustrates an example computer system 900 employed to generate or otherwise process a mask pattern in an embodiment of the present invention.

FIGS. 10a-10e illustrate contact hole mask patterns to produce contact hole target patterns on a substrate according to example embodiments.

FIG. 11a illustrates a deep trench target pattern.

FIG. 11b illustrates a mask pattern for producing the deep trench target pattern shown in FIG. 11a.

FIG. 12 illustrates a deep trench image that would be produced on a substrate using the mask pattern of FIG. 11b compared to the deep trench target pattern.

FIGS. 13a, b and c show alternative rectilinear mask patterns for producing the deep trench pattern shown in FIG. 11a.

### DETAILED DESCRIPTION OF THE INVENTION

Reference will now be made in detail to a particular embodiment of the invention, examples of which are illustrated in the accompanying drawings. While the invention will be described in conjunction with the particular embodiments, it will be understood that it is not intended to limit the invention to the described embodiments. To the contrary, it is intended to cover alternatives, modifications, and equivalents as may be included within the spirit and scope of the invention as defined by the appended claims.

A contact hole is generally represented in a circuit design as a square, a rectangle, a polygon or other similar shape, to be reproduced as faithfully as possible on a substrate in a lithography process, laser-writer, or direct-write tool. Although it is possible to represent such a contact hole as a corresponding rectangle (or square or polygon), at pattern feature sizes comparable to the wavelength of the exposure light used in the exposure process, exposure light interference generally causes such a straightforward mask design to produce a pattern on the substrate that is distorted when compared to the mask pattern. While optical proximity correction (OPC) attempts to address this issue by pre-distorting the rectangle, for example by adding serifs to the rectangle or by using assist features to compensate for effects of adjacent features, this approach may produce results that do not print correctly or do not print robustly. Example embodiments of the present invention use novel mask pattern designs for contact holes, as well as systems and methods for using such novel patterns to form contact holes.

Although the discussion above and below uses the terms contact, contact pattern, contact holes, etc., it is understood that these patterns apply to any process and any design in which the goal is to print a small square, rectangle, circle, or other similar small shape on a substrate, even if the pattern is not intended to be a contact hole. For example, such patterns could be used for vias, trench designs, or other uses.

As used herein, a mask generally includes a transparent material such as glass, borosilicate glass, or fused silica having a layer of opaque or partially transmitting material formed thereon. A mask may include additional materials formed under the opaque material such as an adhesion layer. In addition, a mask may include additional materials formed on top of the opaque material such as a bottom anti-reflective coating, a resist (or “photoresist”), and a top anti-reflective layer. The opaque regions may be replaced by regions etched into the transparent material. As used herein, a substrate may comprise a semiconductor wafer, a mask, or any other substrate upon which a contact hole pattern is to be formed using an exposure process and according to a mask bearing a contact hole pattern. The masks in the examples below may be, for example, chrome on glass masks or attenuated phase shift masks.

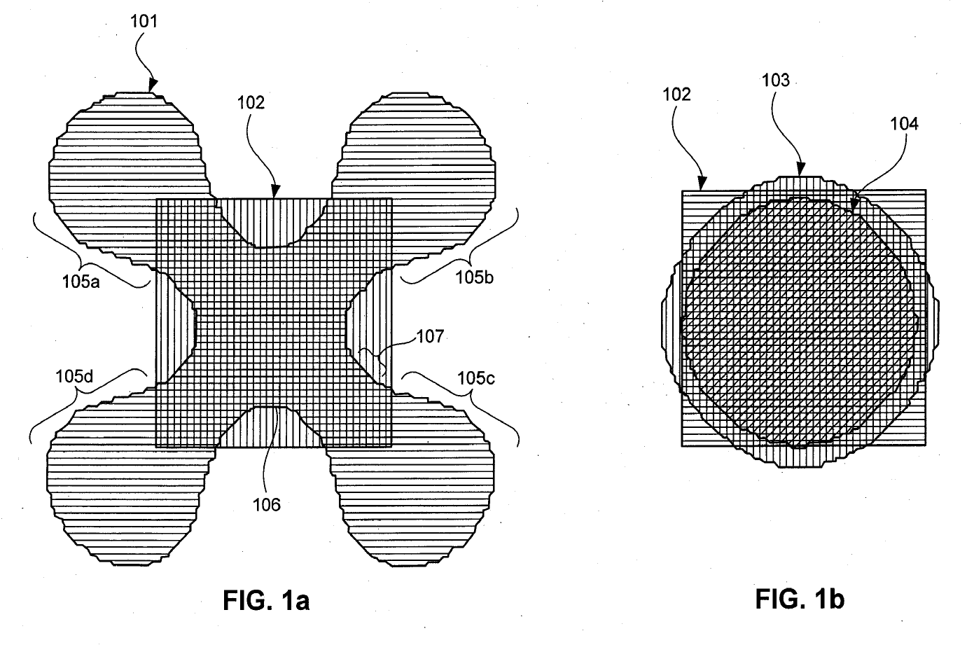

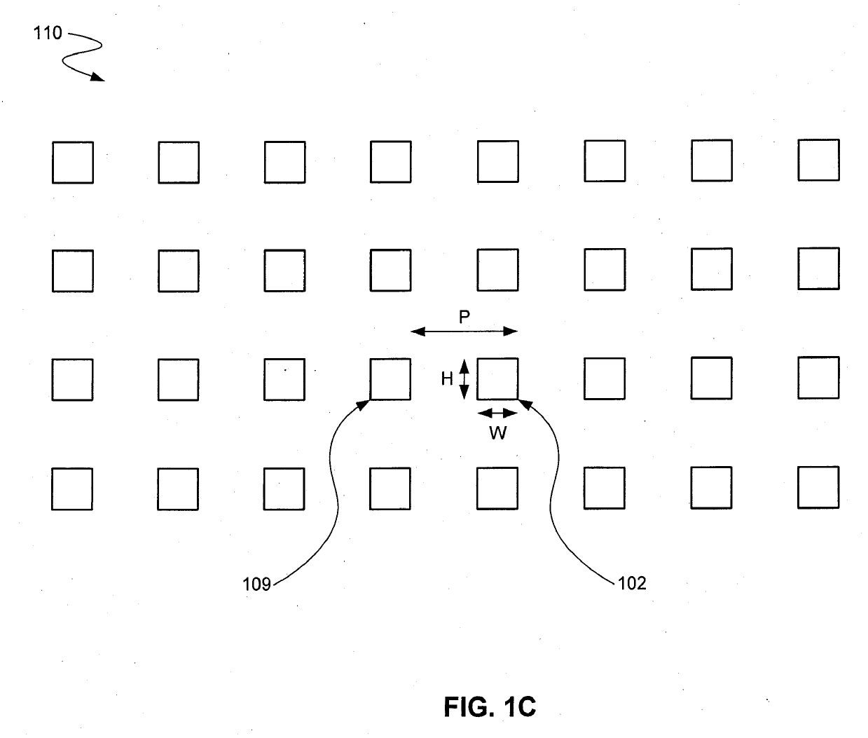

FIG. 1a shows an example contact hole mask pattern 101, in accordance with an embodiment of the present invention. This particular contact hole mask pattern 101 is intended for use in a 280 nm pitch lithography setup to produce the contact hole target pattern 102 on a wafer (or other target substrate). FIG. 1b illustrates some corresponding contour images, with pattern 102 representing the contact hole target pattern of FIG. 1a, pattern 103 representing the contour image at focus plane, and pattern 104 representing the contour image at 100 nm defocus.

FIG. 1c illustrates an array of contact hole target patterns 110, including contact hole target pattern 102 and adjacent contact hole target pattern 109. The pitch P from the side of contact hole target pattern 109 to the corresponding side of contact hole target pattern 102 is 280 nm in this example. Each contact hole target pattern has a height H of 113 nm and a width W of 113 nm. Accordingly, the distance in between adjacent contact hole target patterns is 167 nm in this example. This array could continue for thousands or even millions of contacts. The contact hole mask pattern 101 is used to produce contact hole target pattern 102. The same pattern can be used to produce the other contact hole mask patterns (such as 109) within the array that are surrounded by other contact target patterns. Since the contact target pattern size and pitch is repeated throughout the array, the same contact hole mask pattern 101 may be repeated in an array to produce these structures.

In general, the novel contact hole mask patterns of the present invention comprise a plurality of peripheral regions formed around a target area in which the contact hole is to be formed, wherein the peripheral regions can be visually described as roughly resembling “lobes”, “arms”, “fingers”, “fins”, “leaves”, “flower petals”, “propellers”, “ovals”, “blobs” or similar features, extending approximately along axes which run from the center of the pattern towards the periphery of the pattern. These regions are hereinafter referred to generally as “lobes”. The peripheral regions (“lobes”) in an n-lobed pattern may be substantially symmetric with respect to

$$( \frac{360 °}{n} )$$

rotations about a center of the target area, or they may be non-symmetrically placed to accommodate for interference with other nearby patterns.

In the example of FIG. 1a, the contact hole target pattern is a square with sides of 113 nm and the pitch of the contact holes within the array is 280 nm. The wavelength of light used for the lithography in this example is 193 nm. The relative sizes of the contact hole target pattern 102 and the contact hole mask pattern 101 are approximately to scale in FIG. 1a. As shown in FIG. 1a, the contact hole mask pattern 101 has four lobes 105a, b, c and d. In this example the lobes are symmetrically disposed around the contact hole target pattern 102 at the four corners of the square contact hole target pattern. Each lobe is offset from the adjacent lobes by about 90 degrees. The four lobes are connected to a center region 106 by a neck 107. The width and height of the center region is about 60% of the size of the side of the contact hole target pattern in this example. In other examples, the length and width of the center region may range from 10-100% of the size of the side of the contact hole target pattern, or any range subsumed therein. In some examples, there is no center region. In the example of FIG. 1a, the length of the neck is about 20% of the length of a side of the contact hole target pattern and extends from the center region 106 to the point where the width starts expanding as part of the lobe 105. In other examples, the length of the neck may range from 5-50% of the size of the side of the contact hole target pattern, or any range subsumed therein. In some examples, there is no neck. The length of each lobe (along its central axis) is about 70% of the length of a side of the contact hole target pattern. In this example, most of the lobe (more than two thirds) extends outside of the region where the contact hole target pattern is desired to be printed. In other examples, the lobe may extend outside of the region of the contact hole target pattern by about 40 percent to more than 90 percent, or any range subsumed therein. These are examples only and other patterns of this general shape may be used as well.

In the example of FIG. 1b, the relative sizes of the contact hole target pattern 102, pattern 103 at the focus plane and pattern 104 at 100 nm defocus are approximately to scale. Pattern 103 at the focus plane is approximately circular with a diameter about equal (within about +/−5% or less) to the length of the side of the contact hole target pattern 102 (about 113 nm in this example). In other examples, the pattern at the focus plane may have a width within +/−1-20% percent the length of the side of the contact hole target pattern, or any range subsumed therein. In the example of FIG. 1b, the pattern 104 at 100 nm defocus has a diameter about 10-20% larger than the diameter of pattern 104 and of the side of contact hole target pattern 102. In other examples, the pattern at 100 nm defocus may have a width within +/−1-20% percent the length of the side of the contact hole target pattern, or any range subsumed therein.

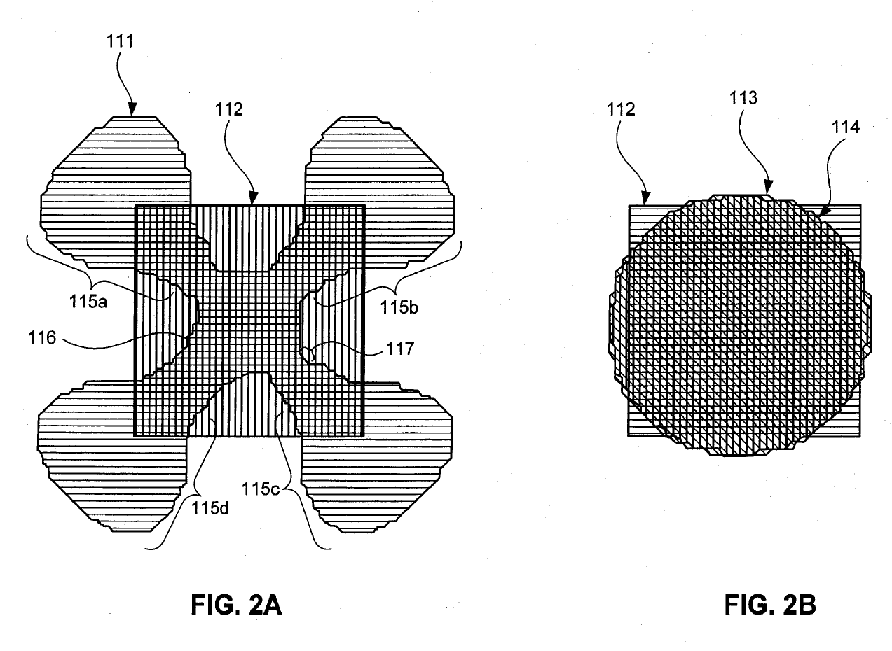

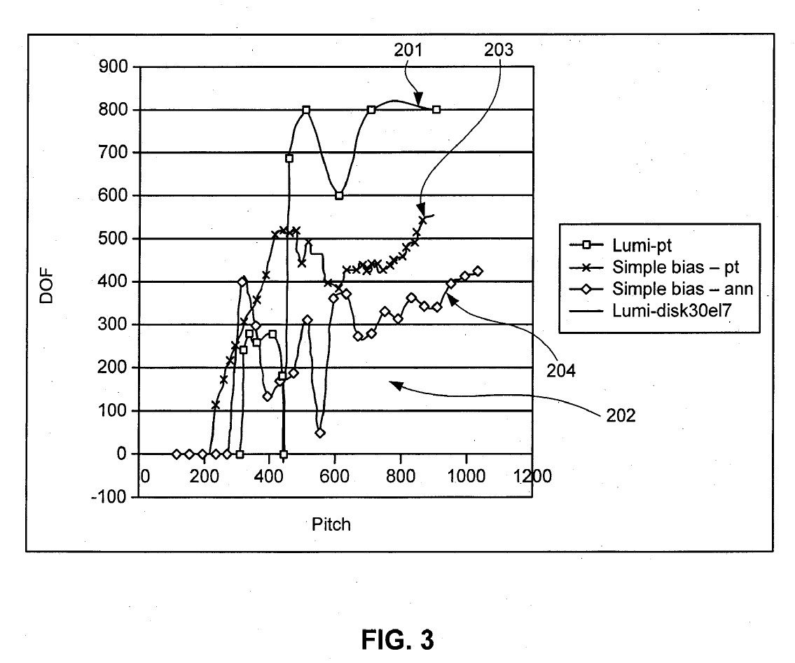

The exact shape and dimensions of mask patterns generally depend on the optical settings and other parameters of the particular process. The shape will also depend upon the other patterns or contacts in the vicinity of the particular contact under consideration. For example, FIG. 2a shows another example contact hole mask pattern 111 which was prepared for a 380 nm pitch lithography setup to produce the contact hole target pattern 112 on a wafer. Note that the connections between the “lobes” of pattern 111 are thinner than the corresponding connections between the “lobes” of pattern 101. The accompanying FIG. 2b illustrates corresponding contour images, with pattern 112 representing the contact hole target pattern of FIG. 2a, pattern 113 representing the contour image at focus plane, and pattern 114 representing the contour image at 100 nm defocus.

In the example of FIG. 2a, the contact hole target pattern may be within an array similar to FIG. 1c and have sides of length 113 nm, although the pitch P is 380 nm in this example. The wavelength of light used for the lithography in this example is 193 nm. The relative sizes of the contact hole target pattern 112 and the contact hole mask pattern 111 are approximately to scale in FIG. 2a. As shown in FIG. 2a, the contact hole mask pattern 111 has four lobes 115a, b, c and d. In this example the lobes are symmetrically disposed around the contact hole target pattern 112 at the four corners of the square contact hole target pattern. Each lobe is offset from the adjacent lobes by about 90 degrees. The four lobes are connected to a center region 116 by a neck 117. The width and height of the center region is about 40% of the size of the side of the contact hole target pattern in this example. In the example of FIG. 2a, the length of the neck is about 10-20% of the length of a side of the contact hole target pattern and extends from the center region 116 to the point where the width starts expanding as part of the lobe 115. The length of each lobe (along its central axis) is about 70% of the length of a side of the contact hole target pattern. In this example, most of the lobe (more than two thirds) extends outside of the region where the contact hole target pattern is desired to be printed. These are examples only and other patterns of this general shape may be used as well.

In the example of FIG. 2b, the relative sizes of the contact hole target pattern 112, pattern 113 at the focus plane and pattern 114 at 100 nm defocus are approximately to scale. Pattern 113 at the focus plane is approximately circular with a diameter a little larger (within about +/−10-20%) than the length of the side of the contact hole target pattern 112 (about 113 nm in this example). In the example of FIG. 2b, the pattern 114 at 100 nm defocus is almost the same as pattern 113.

While the patterns described herein may be used to print a single contact or small number of contacts, example embodiments of the invention may use such patterns in an automated manner on a contact layer of a semiconductor design. In these embodiments, a large number—thousands, tens of thousands, hundreds of thousands, or even millions—of such contact patterns may be used on a single photomask. It is contemplated that a computer system with appropriate software may be used to replicate contact patterns as described herein across a design with a very large number of contacts, for example in an array pattern as described in connection with FIG. 1c.

In some embodiments, design files with these or similar patterns may be generated and provided to software for optical proximity correction (OPC) or other mask optimization techniques prior to using them to manufacture a mask. In other embodiments, design files with these or similar patterns may be used to manufacture masks directly.

In general, the patterns described herein can be used in photolithography processes using off-axis illumination, dipole illumination, quadropole illumination, quasar illumination, incoherent illumination, coherent illumination, or any other illumination aperture. Furthermore, the exposure process used may comprise i-line, g-line, 193, 248, immersion, or any other optical lithography wavelength in air, water, or other fluid or gas.

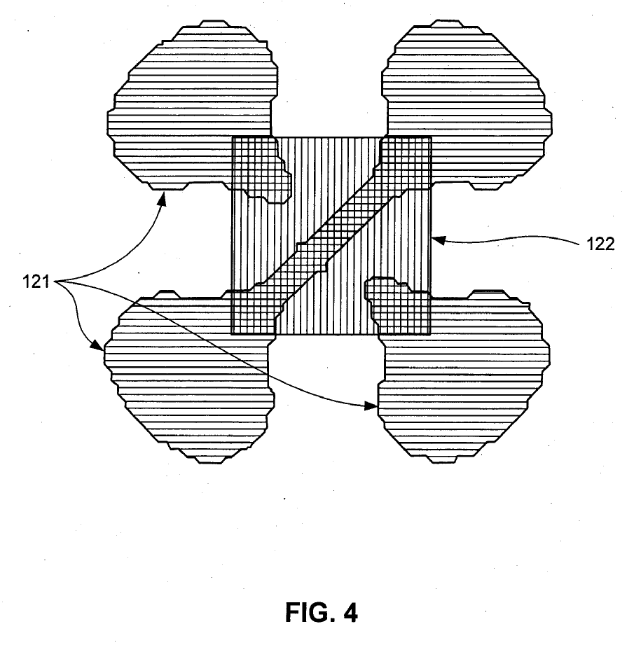

The contact hole mask pattern designs are not restricted to patterns comprising a single connected region (such as mask patterns 101 and 111 of FIGS. 1a and 2a) and may instead exhibit two or more disjoint regions or “pieces”. For example, FIG. 4 illustrates a contact hole mask pattern 121 comprising three disjoint regions, prepared to produce the contact hole target pattern 122 on a wafer. In general, some of the “lobes” of such a pattern may be connected (as are the upper-right and lower-left lobes of FIG. 4), while other lobes may be disjoint (as are the upper-left and lower-right lobes of FIG. 4).

In general, such contact hole mask patterns may comprise any number of lobes which may or may not be connected to other lobes. In example embodiments of the present invention, the contact hole mask patterns, though visually quite different from their respective contact hole target patterns, produce contact holes (on a substrate such as a wafer or a photomask) that are more faithful to the desired contact hole design.

In example embodiments of the present invention, the patterns can also be used to print contact hole patterns on the mask itself using a laser-writer, or to print contact hole patterns on a wafer using direct-write technology. In such cases, the patterns described above would be used as the writing pattern for the laser writer, rather than as mask patterns. However, the same basic principles apply and the resulting patterns (on the mask or on the wafer) will more closely resemble the desired contact hole design than if the original design or a simple biased pattern were used.

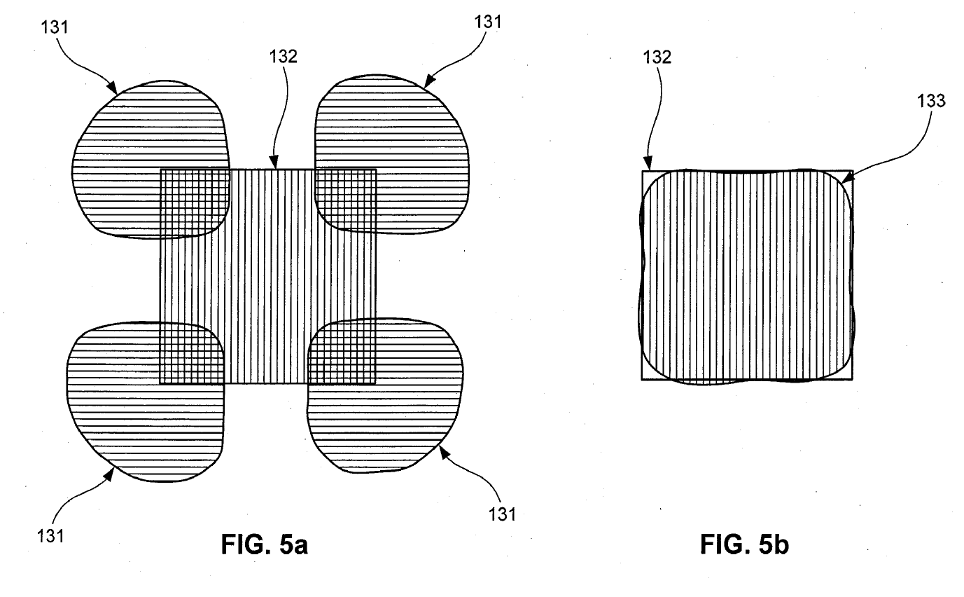

For example, FIG. 5a shows a contact hole pattern 131 generated for use as a laser-writing pattern in order to print a rectangular pattern on a mask, in accordance with an embodiment of the present invention. The pattern 131 was prepared for use in a 300 nm laser-writing setup to produce the rectangular target pattern 132 on a mask. This particular pattern 131 comprises four disjoint “lobes” arranged along the corners of the contact hole target pattern 132, and is an example of a pattern having only disjoint lobes. FIG. 5b shows a contact pattern 133 that would be produced on a mask using the pattern 131 in a 300 nm laser-writing setup. The contact pattern 133 that would be produced on the substrate may be determined through simulation. As can be seen in FIG. 5b, the contact pattern 133 that would be produced is very close to the desired contact target pattern 132. The relative sizes of patterns 131 and 132 in FIG. 5a and of patterns 132 and 133 in FIG. 5b are approximately to scale.

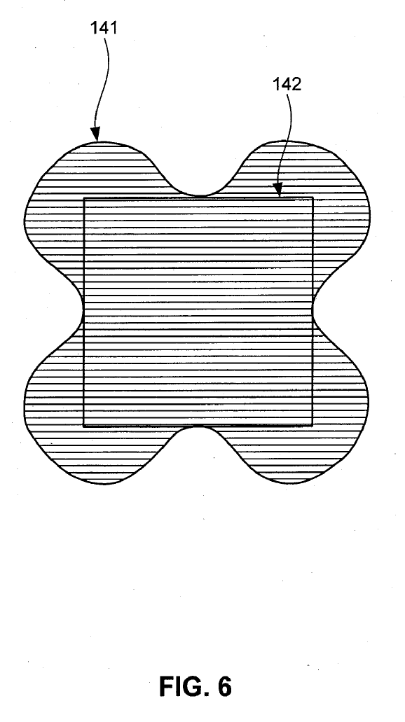

FIG. 6 shows yet another example of a contact hole pattern 141 generated for use in order to produce the rectangular contact hole target pattern 142 on a mask, in accordance with an embodiment of the present invention. In this particular pattern 141 the connections between the four “lobes”, arranged along the corners of to contact hole target pattern 142, are thick and blend together, producing the single connected contact hole pattern 141. As in the above examples, the relative sizes of pattern 141 and 142 are approximately to scale.

As illustrated in exemplary embodiments above, a contact hole mask pattern may comprise four or more elongated or “lobe”-like regions that extend toward the periphery of the pattern. In some embodiments, such regions may take the shape of leaves, ovals, circles or blobs, as described above. In alternate embodiments, these shapes can be approximated using fewer peripheral regions (for example using two or three leaves, ovals, circles or blobs, etc.) or more peripheral regions (for example using five, six, seven, eight or more leaves, ovals, circles or blobs, etc.). In some embodiments, the peripheral regions may comprise a large number of closely spaced fingers, circles or other shapes which collectively form peripheral regions approximating the shapes described above. The center of the pattern may be empty or may connect two or more of the peripheral regions by a narrow bridge pattern or by a block, circle or oval approximately in the center of the peripheral regions.

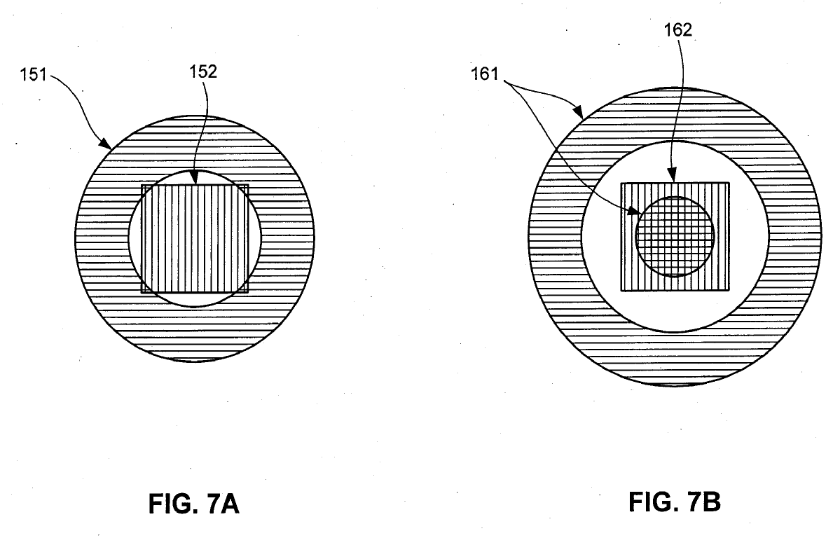

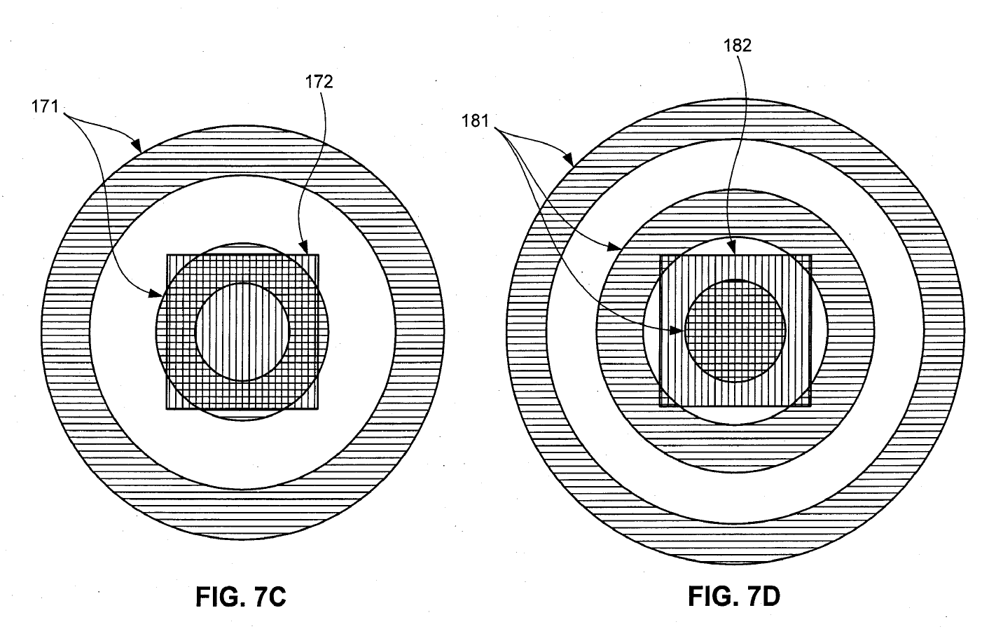

In other embodiments of the present invention, a contact hole mask pattern comprises one or more concentric circles. Examples of such embodiments are illustrated in FIGS. 7a, 7b, 7c and 7d. FIG. 7a shows a contact hole mask pattern 151 generated in order to produce the rectangular contact hole target pattern 152 on a substrate. Pattern 151 comprises a ring having its center approximately at the center of the target pattern 151. The ring may overlap with the target pattern 152 (when the two patterns are viewed in superposition), such as shown in FIG. 7a, or it may be disjoint from the target pattern 152.

FIG. 7b shows a contact hole mask pattern 161 for producing the target pattern 162 on a substrate, in accordance with an embodiment of the present invention. Mask pattern 161 comprises a disk and a ring which are approximately concentric, disjoint and have their centers approximately at the center of the target pattern 162. The target pattern 162 may fully cover the disk (when viewed in superimposition) such as shown in FIG. 7b, or it may partially cover the disk. Alternatively, the disk may be replaced with a square, a polygon or some other geometry.

FIG. 7c illustrates a contact hole mask pattern 171 for producing the target pattern 172 on a substrate, in accordance with an embodiment of the present invention. Mask pattern 171 comprises two rings which are approximately concentric, disjoint and have their centers approximately at the center of the target pattern 172. In general, the mask pattern may comprise any number of rings which may or may not overlap with the target pattern 172.

FIG. 7d shows a contact hole mask pattern 181 for producing the target pattern 182 on a substrate, in accordance with an embodiment of the present invention. Mask pattern 181 comprises a disk and two rings which are approximately concentric, disjoint and centered at approximately the same point as the target pattern 182. In general, such a mask pattern may comprise any number of rings with a disk, a square, a polygon or some other geometry in the center.

The mask patterns described above containing curves or circles can also be made using Manhattan or rectilinear geometries. For example, a set of concentric squares could be used instead of concentric circles. Alternatively, a Manhattan polygon that uses a stair-step type approximation to a circle could be used. In another variation, the “circle” could be an oval or other shape that surrounds the location of the intended contact, and could be curved or could be approximated with a Manhattan stair-step. In another variation, the circle or other surrounding shape could have a break, and only partly surround the location of the intended contact. As with other patterns described previously, the exact shape may depend upon a variety of factors, including the illumination, the process, and other surrounding patterns.

The mask patterns described above may comprise chrome regions or attenuated phase-shift regions which block light or attenuate light. The mask patterns may be glass openings in a chrome or attenuated phase-shift mask. The mask patterns may be the patterns described by a laser-writer in a direct-write or mask writing process, or they may be the inverses of such patterns.

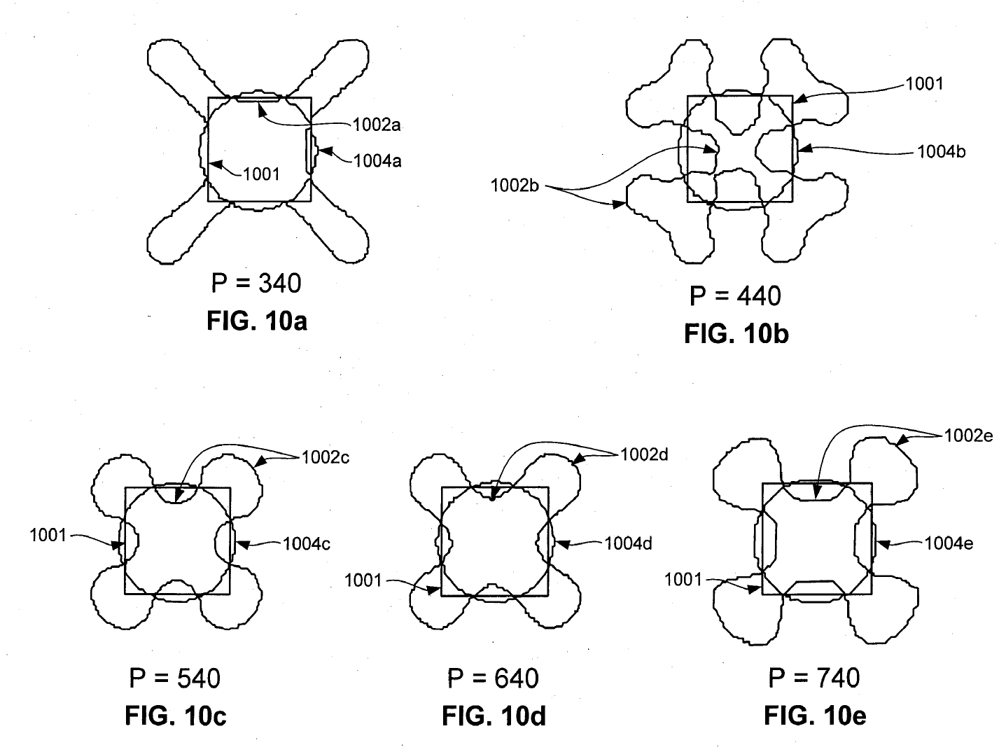

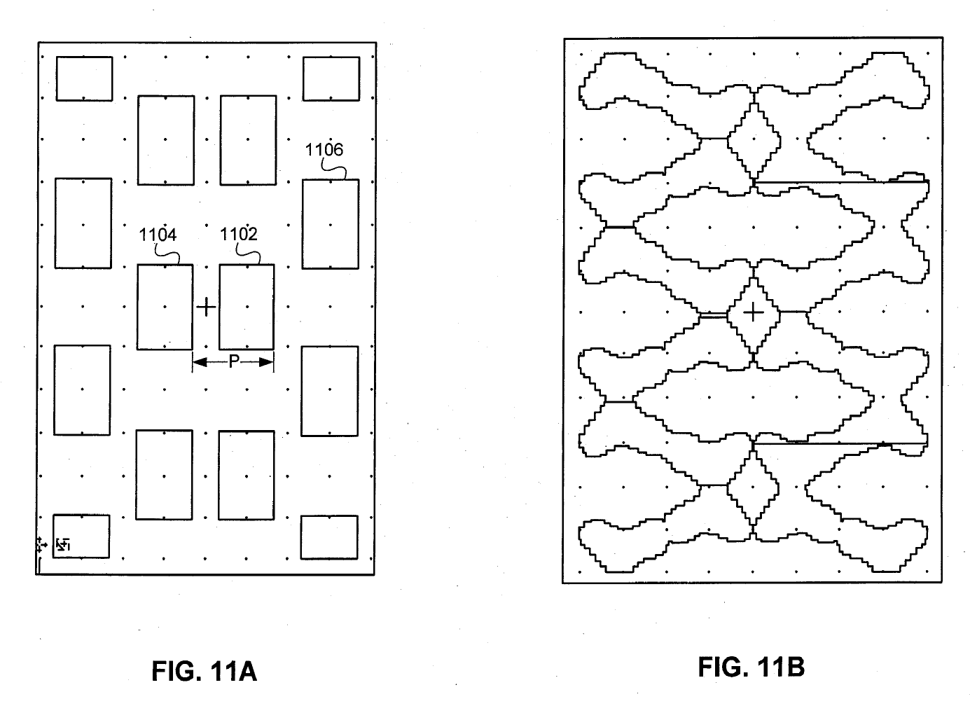

FIG. 10a shows an embodiment of the present invention. A contact pattern resembling the pattern shown in the figure we call a cross-type contact pattern. One aspect of the particular embodiment of a cross-type contact in FIG. 10a is that the contact pattern contains elongated protruding lobes. Another aspect of the particular embodiment is that the lobes are longer then they are wide. In the example embodiment shown, they are more than twice as long as they are wide. In other embodiments, they may be wider than they are long. Still another aspect of the embodiment shown is that the length of the lobes are each comparable to the size of the contact itself. For instance, the length of the lobes may be equal to the length of a side of the target contact pattern or may be within the range of +/−1-5% of such length or any range subsumed therein.

FIG. 10b shows an embodiment of the present invention. A contact pattern resembling the pattern shown in the figure we call a triangle-cross-type contact pattern. One aspect of the embodiment shown in FIG. 10b is that the lobes surrounding the contact pattern are roughly triangular in nature. Another aspect of the particular embodiment is that the sides of the triangles are roughly comparable to the diameter of the contact. In other embodiments, the sides could be longer than the diameter of the contact, shorter than the diameter of the contact, less than ½ the diameter of the contact, or more than 50% larger than the diameter of the contact. Another aspect of the embodiment shown in FIG. 10b is that the triangular shapes are bent inwards, i.e., rather than the corners of the triangles being connected by an approximately straight line, they are connected by a line which bends toward the center of the triangle. In other embodiments it could bend slightly outward. In other embodiments, the three corners of the triangle could be largely separate lobes, comparable to a three lobed embodiment of the present invention. Generally, any of the contact patterns described herein could be grouped together into a cluster of contact patterns that as a group print a single contact, and such a cluster would be considered a contact pattern in these example embodiments of the present invention.

FIGS. 10c, 10d, and 10e show additional embodiments of the present invention. Contact patterns resembling the patterns shown in these figures we call cloverleaf-type contact patterns. In the embodiment of FIG. 10c, the lobes somewhat bulbous, whereas the embodiment of 10d has lobes with straighter edges. In the embodiments shown in FIGS. 10c, d, and e, the lobes have area roughly comparable to the area of the central region. In other embodiments, the lobes could have area larger than the central region. In some embodiments, more than 50% larger, or more than twice as large. In other embodiments, the lobes can be smaller than the central region, in some embodiments, less than ½ the size, or less than ¼ the size.

In the embodiments shown in FIG. 10, a variety of lines occur at various angles, and many of the patterns have curved contours. Similarly shaped Manhattan patterns may also be used in example embodiments of the present invention.

In the embodiments shown in FIG. 10, the square target contact pattern 1001 is 113 nm square, the pitch is 340 nm in FIG. 10a, 440 nm in FIG. 10b, 540 nm in FIG. 10c, 640 nm in FIG. 10d and 740 nm in FIG. 10e. The lithography in these examples uses 193 nm wavelength light. The mask patterns are shown at 1002a, 1002b, 1002c, 1002d, and 1002e, for FIGS. 10a-e, respectively. The pattern that would be produced on the substrate is shown by the circular pattern 1004a, 1004b, 1004c, 1004d, and 1004e, respectively. These patterns may be determined by simulation.

In the embodiments shown in FIG. 10 the lobes are each attached to a central region. In the example embodiments, the central region is of various sizes. It is possible for the central region to be smaller than, larger than, or about the same size as the printed contact. In some embodiments, it could be less than ½ the area; in others, less than ¼ the area. In still other embodiments, the central region could be entirely or almost entirely absent. In such embodiments, the contact pattern could consist primarily of the lobes themselves, or the lobes could be attached by connecting regions. The connecting regions may be narrow compared to the size of the contact.

One aspect of the embodiments of the present invention shown in FIG. 10 is that there are four lobes oriented at approximately 90 degrees to one another. Other embodiments may have two or three lobes or more than four lobes. As described previously, the lobes in an n-lobed pattern may be substantially symmetric with respect to

$$( \frac{360 °}{n} )$$

rotations about a center of the target area, or they may be non-symmetrically placed to accommodate for interference with other nearby patterns.

Another aspect of these embodiments is that the four lobes are oriented at a 45 degree angle with respect to the sides of the contact as drawn. In other embodiments they could be oriented perpendicular to the drawn contact, for example, with a contact as shown in FIG. 10a, the lobes could be pointing up, down, left, and right, rather than diagonally. In still other embodiments they could be at other angles. In general, the mask pattern in these example embodiments of the present invention can be rotated by an arbitrary amount and the resulting pattern would still have the desired shape.

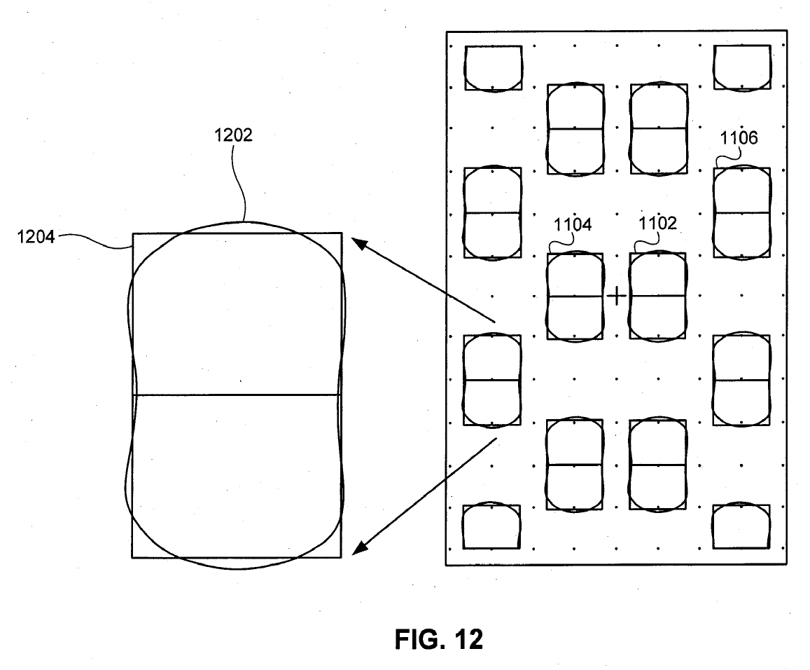

FIG. 11a shows a target design for a deep trench pattern. The size of the trench 1102 is 135×210 nm, the pitch is 200 nm. On one side of trench 1102 is an aligned column of trenches (including 1104). On the other side is an offset column of trenches (including 1106). FIG. 11b shows a mask pattern designed to print the target pattern in FIG. 11a. The mask pattern is intended for a dark field, attenuated phase shifting mask, 193 nm illumination, NA 0.7, annular illumination, with inner sigma 0.57 and outer sigma 0.85. A pattern resembling the pattern shown in FIG. 11b we call an “X-wing” type pattern.

One aspect of the pattern shown in FIG. 11a is that the portions of the mask pattern corresponding to the various trench rectangles are connected to each other. In some embodiments, the patterns may be connected with the connecting regions being relatively thick. For example, in the example embodiment shown in 11a the connecting regions between the diagonally oriented trenches are approximately as thick as the thickness on the photomask of the region corresponding to the trench itself. In the example embodiment shown, the connections between the horizontally neighboring trenches are “just touching”. In other embodiments, the connecting regions between diagonal or horizontal or arbitrarily positioned neighbors may vary in thickness or be non-existent. In some embodiments, the connecting regions, as compared to the thickness of the photomask pattern corresponding to the trench itself, could be slightly thicker or slightly less thick, or less than ½ the thickness, or less than ¼ the thickness, or more than 50% or more than 100% thicker. In the example embodiment shown, the connecting regions are about ½ the thickness of the trench as drawn on the target layer. In other embodiments, the connecting regions could be slightly thicker or slightly less thick, or less than ½ the thickness, or less than ¼ the thickness, or more than 50% or more than 100% thicker. In other embodiments, the connecting regions may be extremely narrow, such that the connections are barely touching, or non existent, in which case the patterns would be isolated from each other. Generally, the connecting regions between different trenches can vary throughout the design, depending upon the target pattern, the shapes in the vicinity, the lithography, stepper, and process conditions, and other factors, and any given trench may have several different types of connections to neighboring trenches or other patterns.

In the example embodiment shown, the target pattern is a repeating array or lattice type structure, consisting of a large number of trenches. In other embodiments, there may be only a single isolated trench or a larger or smaller number. In other embodiments, there may be thousands, tens of thousands, hundreds of thousands, millions, or tens of millions of trenches, which may be arranged in a regular structure, or may be arranged in a more random or arbitrary structure.

It should be noted that in the above discussion, although the terms contact and trench are used with regard to specific example embodiments, the mask patterns used for contacts may be used for trenches or vice versa, and either type may be used to print any square, rectangular, circular, or oval pattern, or other small isolated shape.

FIG. 12 illustrates a deep trench image that would be produced on a substrate using the mask pattern of FIG. 11b compared to the deep trench target pattern shown in FIG. 11a. The deep trench pattern that would be produced on the substrate may be determined through simulation. Rows of target patterns are shown in FIG. 12, including target pattern 1102, 1004 and 1106. A target pattern 1204 from one of the rows is also shown in enlarged form. The simulated pattern that would be produced for target pattern 1204 is shown at 1202. The pattern 1202 closely matches the target pattern 1204, but has curved ends approximating the rectangular ends of the target pattern. Simulated patterns that would be produced on the substrate are also shown superimposed over each of the target patterns in the rows shown in FIG. 12.

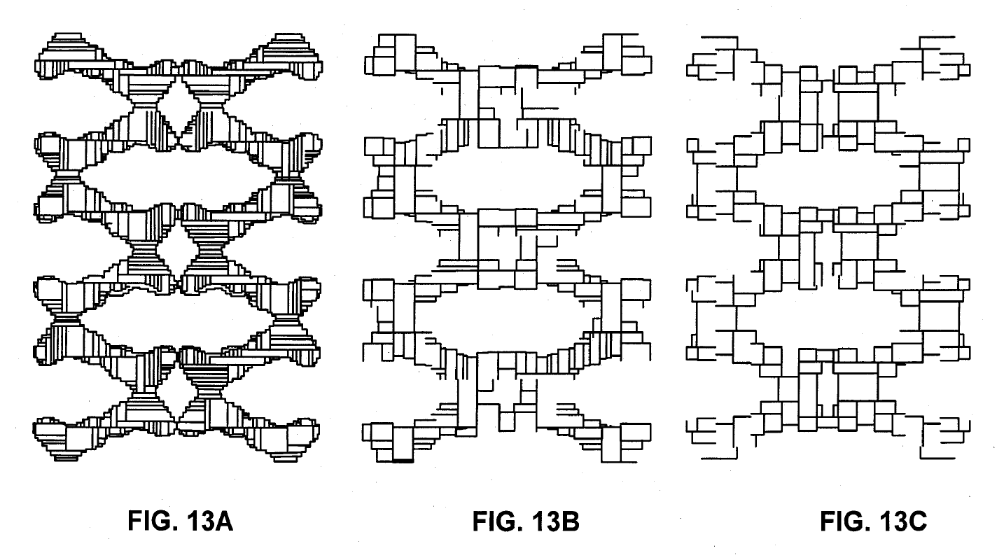

FIG. 13 shows three example embodiments for a mask pattern of the type shown in FIG. 11b, with the minimum segment length varied in each embodiment. In FIG. 13a the minimum segment length is 10 nm. In FIG. 13b it is 30 nm. In FIG. 13c it is 50 nm. In other examples, the minimum segment length may be in the range of from 10-100 nm or any range subsumed therein. These are examples only and other segment lengths may be used as well. Using finer segments may allow in some cases for a more accurate reproduction of the desired target pattern; however, longer segments may make it easier to manufacture the photomask. Various alternative embodiments may be used for each type of pattern described and shown above. A variety of possible related patterns can be generated with varying level of detail or simplicity, using shorter or longer segments, or segments of varying lengths, in various combinations in these alternative embodiments.

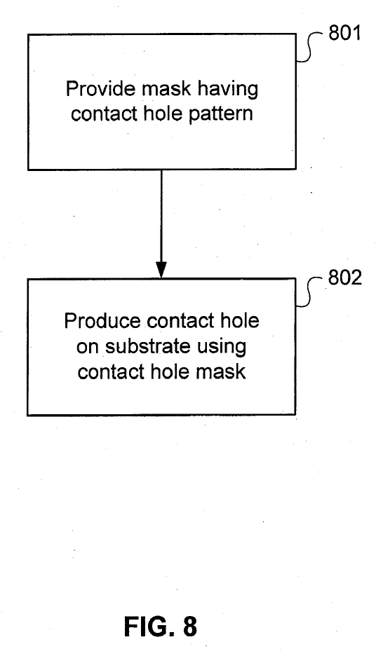

FIG. 8 shows a flow diagram illustrating a method for printing contact holes, in accordance with an embodiment of the present invention. To print a contact hole on a substrate (such as a wafer or a photomask), a mask is provided at step 801. The mask comprises one or more contact hole patterns in a form according to the present invention. The mask is then employed in step 802 to produce a contact hole on the substrate. As described above, the contact hole mask pattern may be visually quite distinct from the desired contact hole target pattern, the novel pattern accounting for distortions and artifacts inherent in the lithography (or laser-writer or direct-write) process and exposure settings in use, thereby increasing the fidelity of the final result produced on the substrate.

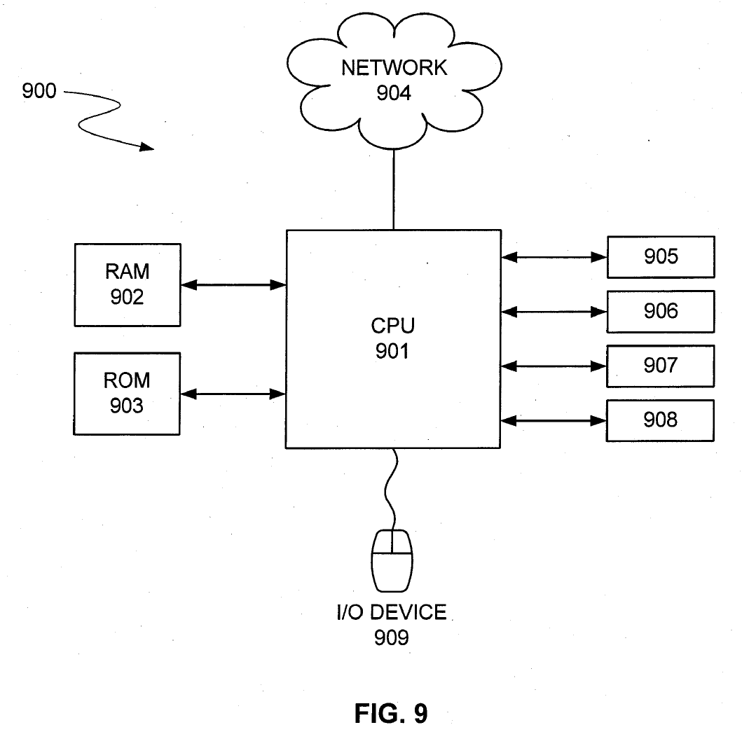

FIG. 9 illustrates an exemplary computer system 900 that may be employed to store or process a mask design or mask design file containing contact patterns according to embodiments of the present invention. Computer system 900 includes one or more central processing units (CPU) 901, random access memory (RAM) 902, read only memory (ROM) 903, one or more peripherals 905, and primary storage devices 906 and 907. As is well known in the art, ROM acts to transfer data and instructions uni-directionally to the CPUs 901, while RAM is used typically to transfer data and instructions in a bi-directional manner. CPUs 901 may generally include any number of processors. Both primary storage devices 906 and 907 may include any suitable computer-readable media. A secondary storage medium 908, which is typically a mass memory device, is also coupled bi-directionally to CPUs 901 and provides additional data storage capacity. The mass memory device 908 is a computer-readable medium that may be used to store programs including computer code, data, and the like. Typically, mass memory device 908 is a storage medium such as a hard disk or a tape which generally slower than primary storage devices 906 and 907. Mass memory storage device 908 may take the form of a magnetic or paper tape reader or some other well-known device. It will be appreciated that the information retained within the mass memory device 908 may, in appropriate cases, be incorporated in standard fashion as part of RAM 902 as virtual memory.

CPUs 901 are also coupled to one or more input/output devices 909 that may include, but are not limited to, devices such as video monitors, track balls, mice, keyboards, microphones, touch-sensitive displays, transducer card readers, magnetic or paper tape readers, tablets, styluses, voice or handwriting recognizers, or other well-known input devices such as, of course, other computers. Finally, CPUs 901 are coupled to a communication link or a computer or telecommunications network 904, such as a digital transmission link, an Internet network or an intranet network, using a network connection as shown generally at 904. With such a communication link, it is contemplated that the CPUs 901 might receive information over the link from the network, or might output information over the link to the network in the course of performing the above-described over-sampled data reception and/or transmission steps. Such information, which is often represented as a sequence of instructions to be executed using CPUs 901, may be received from and outputted to the network, for example, in the form of a computer data signal embodied in a carrier wave. The above-described devices and materials will be familiar to those of skill in the computer hardware and software arts. Computer system 900 receives one or more over-sampled data streams and processes them in order to decode transmitted symbols and perform reception, detection and/or other processing steps described above. Computer instructions for performing such reception, detection and/or other processing steps may be stored in the RAM 902, ROM 903, primary storage devices 906 and 907, and/or any other computer-readable media.

Foregoing described embodiments of the invention are provided as illustrations and descriptions. They are not intended to limit the invention to precise form described. Other variations and embodiments are possible in light of above teachings, and it is thus intended that the scope of invention not be limited by this Detailed Description, but rather by Claims following.

We claim:

1. A mask to be used in forming a contact hole on a substrate in approximation with a target pattern, the mask comprising:
a mask pattern for the contact hole;
wherein the mask pattern has a plurality of lobes disposed around the region of the mask corresponding to the target pattern for the contact hole;
wherein at least a portion of each lobe extends outside of the region corresponding to the target pattern; and
wherein the portions of the lobes that extend outside the region corresponding to the target pattern include at least twenty percent (20%) of the area of the mask pattern.

2. The mask of claim 1 wherein the portions of the lobes that extend outside the region corresponding to the target pattern include at least fifty percent (50%) of the area of the mask pattern.

3. The mask of claim 1 wherein the mask pattern includes a central region within the region corresponding to the target pattern.

4. The mask of claim 3 wherein the central region has an area less than twenty five percent (25%) of the region corresponding to the target pattern.

5. The mask of claim 1 wherein the mask pattern includes a central region within the region corresponding to the target pattern and each of the lobes is connected to the central region.

6. The mask of claim 1 wherein the mask pattern includes a central region within the region corresponding to the target pattern and at least one of the lobes is disjoint from the central region.

7. The mask of claim 1 wherein the mask pattern includes a central region within the region corresponding to the target pattern and each of the lobes is disjoint from the central region.

8. The mask of claim 1 wherein the mask pattern does not include a central region corresponding to the center of the target pattern.

9. The mask of claim 1 wherein the plurality of lobes includes at least four lobes.

10. The mask of claim 1 wherein the lobes are disposed symmetrically around the region corresponding to the target pattern.

11. The mask of claim 1 wherein each lobe is offset from an adjacent lobe by about ninety degrees.

12. The mask of claim 1 wherein at least fifty percent (50%) of each lobe extends outside of the region corresponding to the target pattern.

13. The mask of claim 1, wherein each lobe has a length greater than its width.

14. The mask of claim 1, wherein each lobe is approximately triangular.

15. The mask of claim 14, wherein the side of each lobes extends inward from the vertices of the approximately triangular shape of the lobe.

16. The mask of claim 1, wherein each lobe has a narrow portion within the region corresponding to the target pattern and a wider portion outside the region corresponding to the target pattern.

17. The mask of claim 1, the portion of each of the lobes that extends outside the region corresponding to the target pattern has a length of at least fifty percent (50%) of a side of the target pattern.

18. The mask of claim 1, the portion of each of the lobes that extends outside the region corresponding to the target pattern has a length of at least fifty percent (50%) of a diameter of the target pattern.

19. A mask to be used in forming a plurality of contact holes on a substrate in approximation with a target pattern for each of the contact holes, the mask comprising:
a plurality of mask patterns, including a mask pattern corresponding to each of the contact holes;
wherein each mask pattern has a plurality of lobes disposed around the region of the mask corresponding to the target pattern for the respective contact hole;
wherein at least a portion of each lobe extends outside of the region corresponding to the respective target pattern; and
wherein the portions of the lobes that extend outside the region corresponding to the respective target pattern include at least twenty percent (20%) of the area of the mask pattern.

20. The mask of claim 19, wherein the plurality of mask patterns includes at least a thousand mask patterns for forming at least one thousand corresponding contact holes.

21. The mask of claim 19, wherein the plurality of mask patterns is arranged to form an array of corresponding contact holes.

22. A mask to be used in forming a contact hole on a substrate in approximation with a target pattern, the mask comprising:
a mask pattern for the contact hole;
wherein the mask pattern includes an outer ring disposed around the region of the mask corresponding to the target pattern for the contact hole;
wherein most of the outer ring is outside of the region corresponding to the target pattern.

23. The mask of claim 22, wherein the mask pattern further comprises an inner ring that is inside the outer ring.

24. The mask of claim 23, wherein the inner ring is concentric with the outer ring.

25. The mask of claim 22, wherein the mask pattern further comprises a circular region inside the outer ring.

26. The mask of claim 25, wherein the circular region is positioned within the region corresponding to the target pattern.

27. A mask to be used in forming a contact hole on a substrate in approximation with a target pattern, the mask comprising:
a mask pattern for the contact hole;
wherein the mask pattern has a plurality of lobes disposed around the region of the mask corresponding to the target pattern for the contact hole;
wherein a majority of each lobe extends outside of the region corresponding to the target pattern; and
wherein each lobe has a narrow region within the region corresponding to the target pattern and a wider region outside the region corresponding to the target pattern.

28. The mask of claim 27, wherein the plurality of lobes includes at least four lobes.

29. A mask to be used in forming a contact hole on a substrate in approximation with a target pattern, the mask comprising:
a mask pattern for the contact hole;
wherein the mask pattern has a plurality of lobes disposed around the region of the mask corresponding to the target pattern for the contact hole;
wherein each lobe has a width that varies along the length of the respective lobe; and
wherein the widest portion of each lobe is outside the region of the mask corresponding to the target pattern.
